(19) United States
(12) Patent Application Publication
(10) Pub. No.: US 2010/0187660 A1
(43) Pub. Date: Jul. 29, 2010

(54) Method To Create SOI Layer For 3D-Stacking Memory Array

(76) Inventors: Sanh Tang, Boise, ID (US); David Wells, Boise, ID (US); Eric Blomiley, Boise, ID (US)

Correspondence Address: COOL PATENT, P.C.;c/o CPA Global, P.O. BOX 52050, MINNEAPOLIS, MN, 55402, US

(21) Appl. No.: 12/359,412

(22) Filed: Jan. 26, 2009

(51) Int. Cl. H01L 29/04; H01L 21/20

(52) U.S. Cl. 257/627; 438/481; 257/E21.09; 257/E29.004

(57) ABSTRACT

A 3-D stacked semiconductor device is formed by forming a trench is formed through a top surface in a dielectric layer to expose the crystalline silicon layer having a (100) crystal plane, such that the trench walls are parallel to a <100> direction. Epitaxial silicon is grown between the trench walls to a level that is below the top surface of the dielectric layer. Epitaxial silicon is laterally grown using the top portion of the epitaxially grown silicon as a seed to form a laterally grown epitaxial layer having a (100) crystal plane on the dielectric layer.

### TECHNICAL FIELD

Embodiments described herein are generally directed to the field of semiconductor device fabrication and, more particularly, to produce a silicon-on-oxide (SOI) layer that can be used for three-dimensional (3D) stacked integrated circuits.

### BACKGROUND

As semiconductor memory cells become increasingly difficult to shrink, stacking memory over CMOS or stacking a memory array by repeating the processes forming the array has been increasingly gaining interest as a low-cost solution for increasing efficiency and scaling. While repeating the processes of the memory array for 3D stacking can be performed in a laboratory environment, transferring or creating a uniform, low-defect silicon layer that satisfies performance and reliability qualities that are similar to an SOI layer in a manufacturing environment for 3D stacking has been an obstacle. Laser recrystalization approaches or approaches that transfer a layer by wafer bonding have been considered, but both techniques are costly due to new tooling requirements, or are too defective for very long memory strings and/or large devices.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIG. 1 depicts an exemplary silicon-comprising a semiconductor wafer;

FIG. 2 depicts a three-dimensional cross-sectional view showing cuts oriented along different crystalline direction of the silicon-comprising material;

FIGS. 3A-3D depicts different views of an exemplary embodiment of a semiconductor device during the initial stages of fabrication of an integrated circuit according to the subject matter disclosed herein;

FIGS. 4A-4D depict different views of the exemplary embodiment of the semiconductor device depicted in FIGS. 3A-3D after an STI oxide fill and chemical-mechanical planarization (CMP) according to the subject matter disclosed herein;

FIGS. 5A-5D depict different views of the exemplary embodiment of semiconductor device depicted in FIGS. 4A-4D after NAND cell formation according to the subject matter disclosed herein;

FIGS. 6A-6D depict different views of the exemplary embodiment of semiconductor device depicted in FIGS. 5A-5D after an oxide-fill step and reactive-ion etching (RIE) according to the subject matter disclosed herein;

FIGS. 7A-7D depict different views of the exemplary embodiment of semiconductor device depicted in FIGS. 6A-6D after an oxide-fill step and CMP according to the subject matter disclosed herein;

FIGS. 8A-8D depict different views of the exemplary embodiment of semiconductor device depicted in FIGS. 7A-7D after formation of a common-source (CE) slot according to the subject matter disclosed herein;

FIGS. 9A-9D depict different views of the exemplary embodiment of semiconductor device depicted in FIGS. 8A-8D after epitaxial (EPI) silicon is selectively grown in the common-source (CE) slot according to the subject matter disclosed herein;

FIGS. 10A-10D depict different views of the exemplary embodiment of semiconductor device depicted in FIGS. 9A-9D after etching oxide to about 700 Å or more below the top of the EPI silicon according to the subject matter disclosed herein;

FIGS. 11A-11D depict different views of the exemplary embodiment of semiconductor device depicted in FIGS. 10A-10D after selective lateral overgrowth of EPI silicon using the EPI silicon as a seed according to the subject matter disclosed herein;

FIGS. 12A-12D depict different views of the exemplary embodiment of semiconductor device depicted in FIGS. 11A-11D after CMP of the laterally grown EPI silicon using oxide hedges as a stop for the CMP according to the subject matter disclosed herein;

FIGS. 13A and 13B depict different views of exemplary embodiment of semiconductor depicted in FIGS. 12A-12D after two layers of NAND arrays have been fabricated in a stacked manner according to the subject matter disclosed herein; and

FIGS. 14A and 14B depict different views of exemplary embodiment of semiconductor depicted in FIGS. 13A and 13B configured to be a multiple stack NAND memory array according to the subject matter disclosed herein.

It will be appreciated that for simplicity and/or clarity of illustration, elements depicted in the figures have not necessarily been drawn to scale. For example, the dimensions of some of the elements may be exaggerated relative to other elements for clarity. The scaling of the figures does not represent precise dimensions and/or dimensional ratios of the various elements depicted herein. Further, if considered appropriate, reference numerals have been repeated among the figures to indicate corresponding and/or analogous elements.

### DETAILED DESCRIPTION

Embodiments of techniques are described herein for forming a layer having performance and qualities of a silicon-on-oxide (SOI) layer that can be used for three-dimensional (3D) stacked integrated circuits. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments. Additionally, the word “exemplary” is used herein to mean “serving as an example, instance, or illustration.” Any embodiment described herein as “exemplary” is not to be construed as necessarily preferred or advantageous over other embodiments.

It should be understood that the exemplary semiconductor materials disclosed herein need not be silicon-based. For example, the semiconductor materials can be silicon-germanium, germanium, or gallium-arsenide. As used herein the terms “wafer” and “substrate” may include a number of semiconductor-based structures that have an exposed semiconductor surface. When reference is made to “wafer” and “substrate” in the following disclosure, previous process steps may have been utilized to form regions or junctions in or on the semiconductor structure and/or foundation. When reference is made to a substrate assembly, various process steps may have been previously used to form or define regions, junctions, various structures or features, and openings such as capacitor plates or barriers for capacitors. The term “structure” and “structures” should be understood to comprise silicon, silicon-on-insulator (SOI), silicon-on-sapphire (SOS), doped, and undoped semiconductors. The term “structure” should be understood to include epitaxial layers of silicon supported by a base semiconductor foundation. The base semiconductor foundation is typically the lowest layer of silicon material on a wafer or a silicon layer deposited on another material.

As used herein, the term “layer” can refer to a layer formed on a substrate using a deposition process, e.g., plasma and/or chemical-vapor deposition (CVD) process. The term “layer” is also meant to include layers specific to the semiconductor industry, such as “barrier layer,” “dielectric layer,” and “conductive layer”. The term “layer” is also meant to include layers found in technology outside of semiconductor technology, such as coatings on glass.

The subject matter disclosed herein relates to techniques for fabricating single or multiple high-quality SOI layers for virtually any stacking or 3D semiconductor device. For example, the subject matter disclosed herein can be used for, but is not limited to, fabricating a NAND cell device, a NOR FLASH cell device, a Personal Computer Random Access Memory (PC-RAM) device, a Zero-Capacitor RAM (Z-RAM, i.e., Floating-body effect RAM) device, a static RAM (SRAM) device, an imager device, a One-Time-Programmable RAM (OTP/RAM) device, an Electronically Erasable Programmable Read Only Memory (EEPROM) device, a logic circuitry device, a Central Processing Unit (CPU) device, a Dynamic RAM (DRAM) device, a Magnetic RAM (MRAM) device, a Ferroelectric RAM (FeRAM) device, and a Resistive RAM (RRAM) device. Moreover, The subject matter disclosed herein provides techniques for fabricating single or multiple high-quality SOI layers for virtually any stacking or 3D semiconductor device in which no new tooling is required and is low cost.

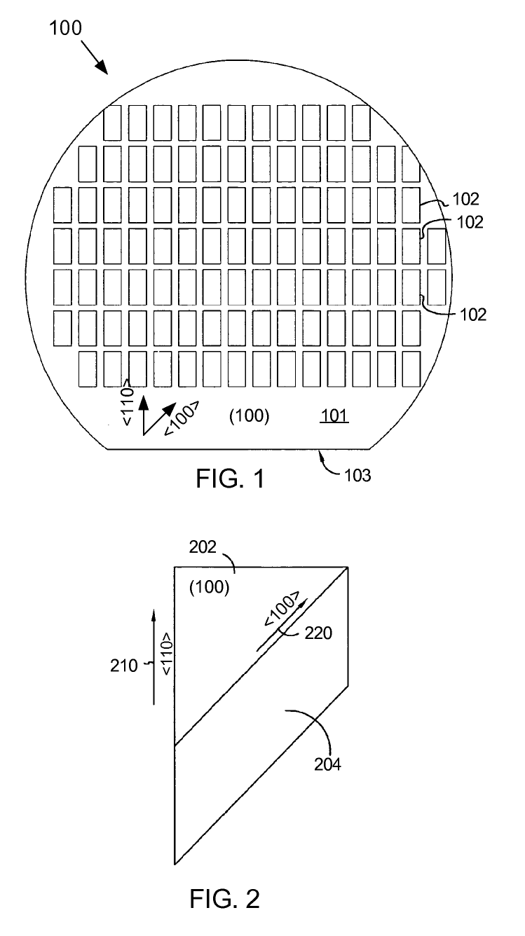

FIG. 1 depicts an exemplary silicon-comprising semiconductor wafer 100. Wafer 100 comprises a number of unsingulated die 102 for undergoing integrated circuit fabrication and processing thereupon. As shown in FIG. 1, wafer 100 is provided in a well-known manner with a registration mark, shown in FIG. 1 as wafer edge 103, which is used for orienting the integrated circuit in the <110> direction during fabrication and processing steps. As shown, such wafers 100 are also provided with a top surface 101 that exposes the (100) crystalline plane of the silicon thereon. Embodiments of the present disclosure, which are discussed more below, involve rotating the wafer 100 such that integrated circuit fabrication and processing are oriented along the <100> direction of the silicon crystalline structure provided on the wafer 100.

FIG. 2 depicts a three-dimensional cross-sectional view showing cuts oriented along different crystalline direction of the silicon-comprising material. The three-dimensional view of FIG. 2 shows a top surface 202 having a (100) silicon crystal plane. FIG. 2 shows a three-dimensional cut 210 as could be made into the silicon-comprising material of the wafer in the <110> direction of silicon crystalline structure. FIG. 2 additionally shows a three-dimensional cut 220 as is made into the silicon-comprising material of the wafer along the <100> direction such that the walls, e.g., the surface 204, also run along the <100> direction and have a (100) silicon crystal plane. According to the exemplary embodiments described herein, the wafer, e.g., wafer 100 shown in FIG. 1, is oriented such that integrated circuit fabrication and processing is performed with cuts being made into the silicon comprising material of the wafer to form walls in the <100> crystal direction versus the <110> crystal direction.

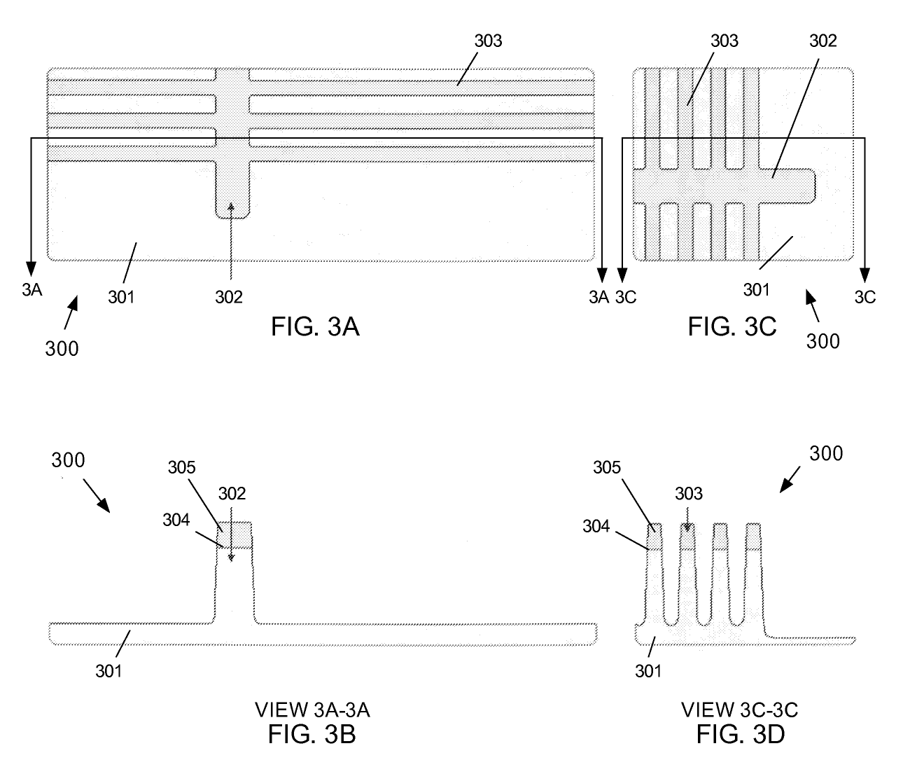

FIG. 3A depicts a top view of an exemplary embodiment of a semiconductor device 300 during the initial stages of fabrication of an integrated circuit. FIG. 3B depicts a cross-sectional front elevation view of semiconductor device 300 as viewed along line 3A-3A in FIG. 3A. FIG. 3C depicts a rotated top view of a portion of semiconductor device shown in FIG. 3A. FIG. 3D depicts a cross-sectional side elevation view of semiconductor device 300 as viewed along line 3C-3C in FIG. 3C. As depicted in FIGS. 3A-3D, semiconductor device 300 comprises a semiconductor substrate 301, formed from, for example, crystalline silicon, an exemplary embodiment of a structure 302 and an exemplary embodiment of a plurality of fin structures 303, of which only one fin structure of the plurality is indicated for clarity. In later processing steps, structure 302 will be utilized as a continuous common-source structure. Structure 302 and fin structures 303 are formed on substrate 301 using a well-known shallow-trench-isolation (STI) fabrication technique. While only a small portion of semiconductor substrate 301 is shown, it should be understood that numerous other structures 302 and 303 could also be formed on the semiconductor substrate 301. In one exemplary embodiment, the wafer of which silicon substrate 301 is part has been rotated 45 degree so that the Si <100> plane will be exposed when slots are formed during subsequent processing for silicon seeding.

Structure 302 is formed to be continuous by using a pitch multiplication technique on currently available masks that have been modified by adding a bridging tab. According to one exemplary embodiment, subsequent processing steps will form continuous structure 302 to bridge active areas (AAs) together in order to provide continuous silicon for EPI growth. It should be understood, however, that structures 302 and 303 could be formed to extend in one or more selected directions and for any selected length. A tunnel gate oxide 304 is formed in a well-known manner on structures 301 and 302. Afterward, a polysilicon floating gate 305304 is formed in a well-known manner on tunnel gate oxide 304.

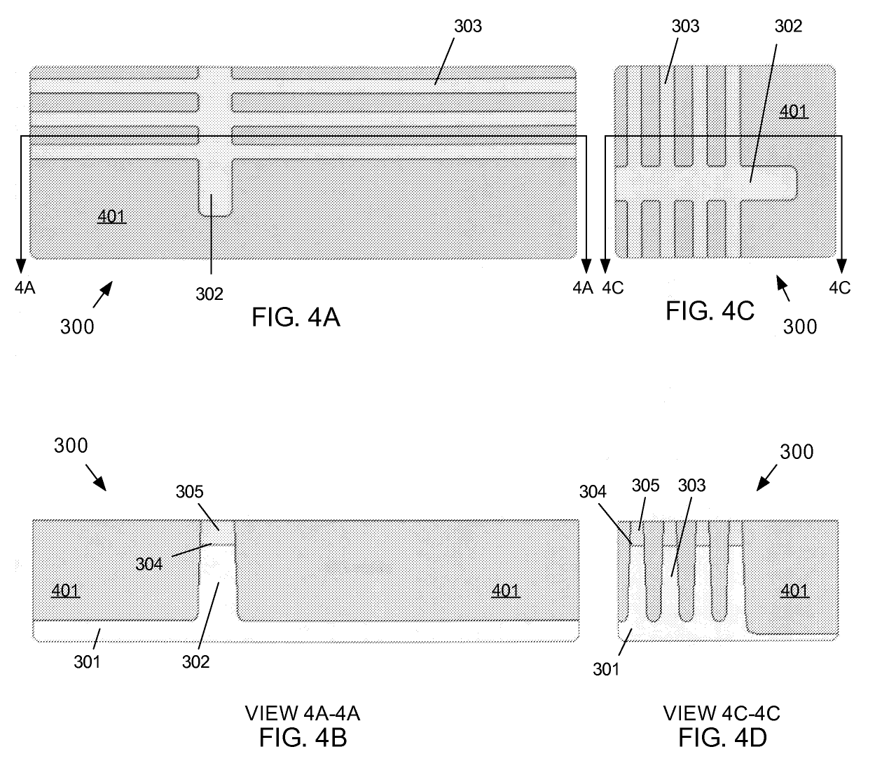

FIG. 4A depicts a top view of the exemplary embodiment of semiconductor device 300 after an STI oxide fill and chemical-mechanical planarization (CMP). FIG. 4B depicts a cross-sectional front elevation view of semiconductor device 300 as viewed along line 4A-4A in FIG. 4A. FIG. 4C depicts a rotated top view of a portion of semiconductor device 300 shown in FIG. 4A. FIG. 4D depicts a cross-sectional side elevation view of semiconductor device 300 as viewed along line 4C-4C in FIG. 4C. At this stage of fabrication, a dielectric material 401, such as silicon dioxide, fills the trenches between structures 302 and 303. Alternatively, Spin-on-Glass (SOG), which is another form of SiO₂, can be used as dielectric material 401. Semiconductor 300 is subjected to a well-known CMP step to planarize the top surface down to polysilicon floating gate 304.

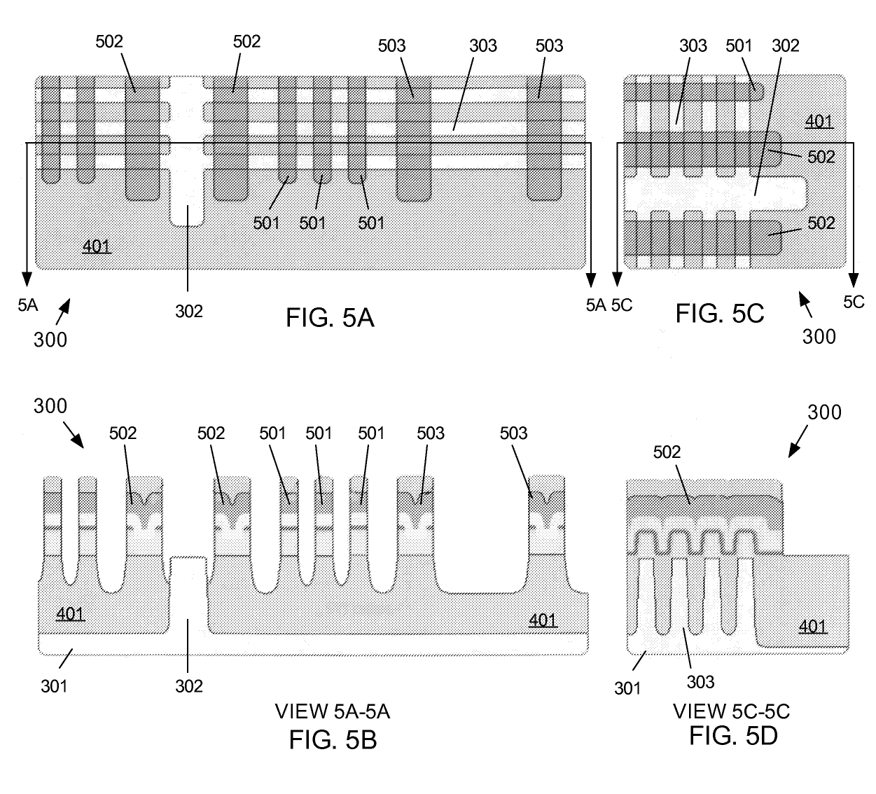

FIG. 5A depicts a top view of the exemplary embodiment of semiconductor device 300 after NAND cell formation. FIG. 5B depicts a cross-sectional front elevation view of semiconductor device 300 as viewed along line 5A-5A in FIG. 5A. FIG. 5C depicts a rotated top view of a portion of semiconductor device 300 shown in FIG. 5A. FIG. 5D depicts a cross-sectional side elevation view of semiconductor device 300 as viewed along line 5C-5C in FIG. 5C. NAND cell formation is performed using well-known techniques to form word lines 501, Select-Gate-Sources (SGS) 502, and Select-Gate-Drains (SGD) 503, of which only a few of each are indicated in FIGS. 5A-5D for clarity. Additionally, peripheral CMOS devices (not shown) can be formed at this stage of fabrication. It should be understood that while semiconductor device 300 has been indicated to be a NAND cell device, other semiconductor devices could be formed, including, but not limited to, a NOR FLASH cell device, a Personal Computer Random Access Memory (PC-RAM) device, a Zero-Capacitor RAM (Z-RAM, i.e., Floating-body effect RAM) device, a static RAM (SRAM) device, an imager device, a One-Time-Programmable RAM (OTP/RAM) device, an Electronically Erasable Programmable Read Only Memory (EEPROM) device, a logic circuitry device, a Central Processing Unit (CPU) device, a Dynamic RAM (DRAM) device, a Magnetic RAM (MRAM) device, a Ferroelectric RAM (FeRAM) device, and a Resistive RAM (RRAM) device.

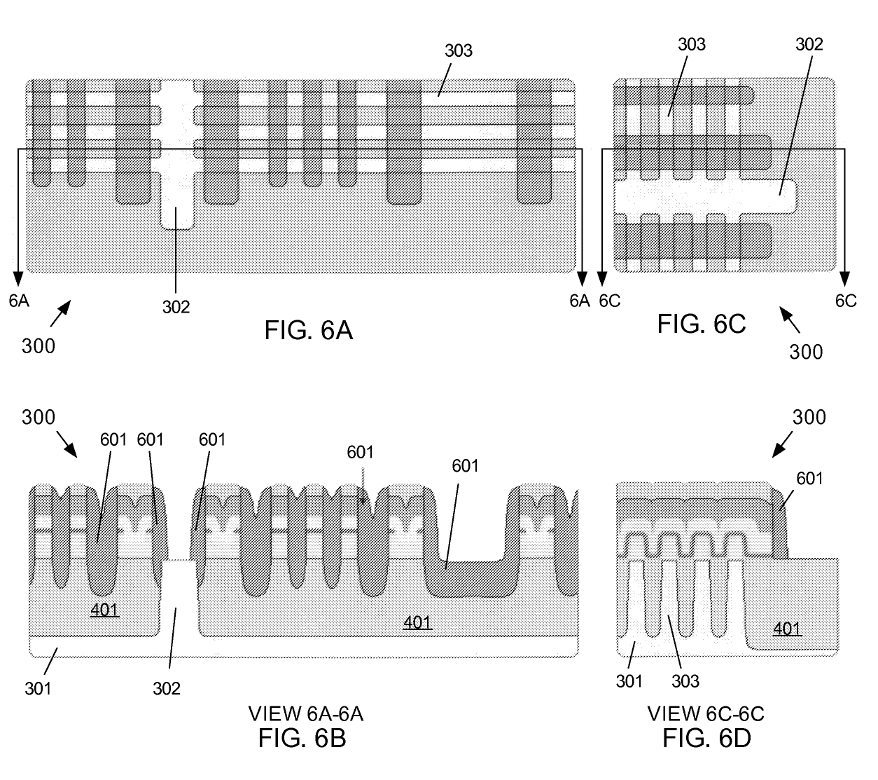

FIG. 6A depicts a top view of the exemplary embodiment of semiconductor device 300 after an oxide-fill step and reactive-ion etching (RIE). FIG. 6B depicts a cross-sectional front elevation view of semiconductor device 300 as viewed along line 6A-6A in FIG. 6A. FIG. 6C depicts a rotated top view of a portion of semiconductor device 300 shown in FIG. 6A. FIG. 6D depicts a cross-sectional side elevation view of semiconductor device 300 as viewed along line 6C-6C in FIG. 6C. As depicted best in FIGS. 6B and 6D, an oxide 601 is formed in a well-known manner on semiconductor 300 and then etched using a well-known reactive-ion etching process. The etching process forms oxide 601 as a spacer oxide. In an alterative exemplary embodiment, oxide 601 could be replaced by silicon nitride, but it should be kept in mind that silicon nitride might not be suitable for a NAND application because silicon nitride traps charges.

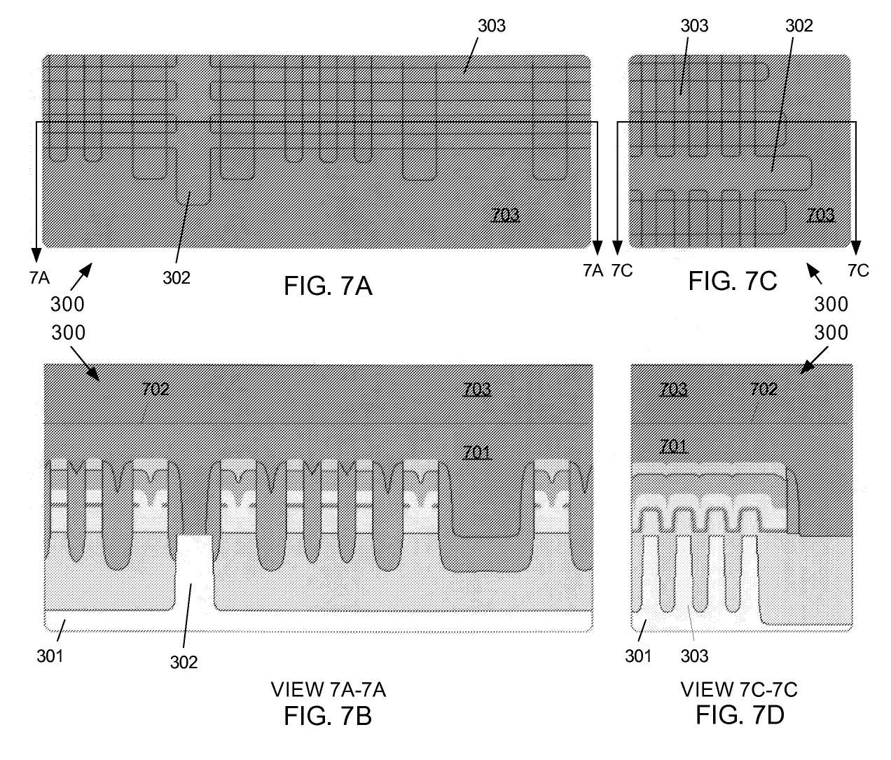

FIG. 7A depicts a top view of the exemplary embodiment of semiconductor device 300 after an oxide-fill step and CMP. FIG. 7B depicts a cross-sectional front elevation view of semiconductor device 300 as viewed along line 7A-7A in FIG. 7A. FIG. 7C depicts a rotated top view of a portion of semiconductor device 300 shown in FIG. 7A. FIG. 7D depicts a cross-sectional side elevation view of semiconductor device 300 as viewed along line 7C-7C in FIG. 7C. As depicted best in FIGS. 7B and 7D, an oxide layer 701, formed from, for example, silicon dioxide, is formed in a well-known manner on semiconductor 300 to fill the gaps between the spaces formed between spacer oxide 601. Oxide layer 701 is then subjected to a well-known CMP process to form surface 702. Another oxide layer 703, formed from, for example, silicon dioxide, is formed in a well-known manner on surface 702 to provide sufficient insulation for the next layer of circuitry that will be formed on oxide layer 703. In an alternative exemplary embodiment, a phosphosilicate glass (PSG), a borophosophsilcate glass (BPSG) or Spin-on-Glass (SOG) could be used for layer 703.

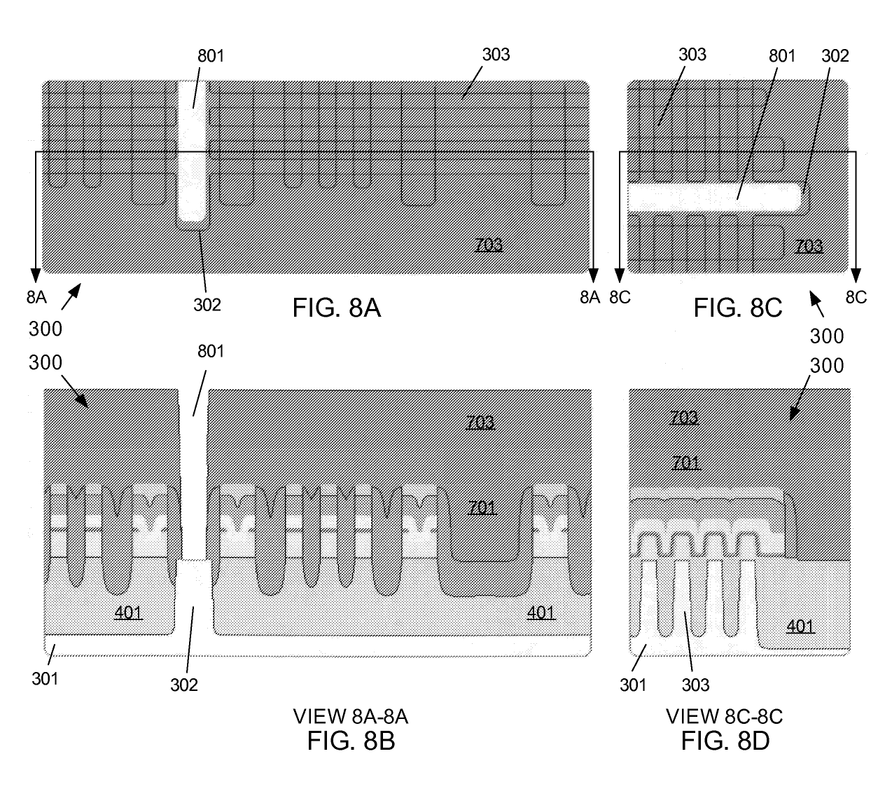

FIG. 8A depicts a top view of the exemplary embodiment of semiconductor device 300 after formation of a common-source (CE) trench 801. FIG. 8B depicts a cross-sectional front elevation view of semiconductor device 300 as viewed along line 8A-8A in FIG. 8A. FIG. 8C depicts a rotated top view of a portion of semiconductor device 300 shown in FIG. 8A. FIG. 8D depicts a cross-sectional side elevation view of semiconductor device 300 as viewed along line 8C-8C in FIG. 8C. Common-source (CE) trench 801 is formed using a well-known manner photomask technique. A well-known Reactive-Ion Etching (RIE) process, such as using a fluoride component, an oxidizing agent, or an inorganic acid, is used to form a trench 801 by clearing all of oxide 701 and 703 to expose structure 302. Structure 302, being formed from silicon, will be used as a seed base to grow epitaxial (EPI) silicon in a subsequent step.

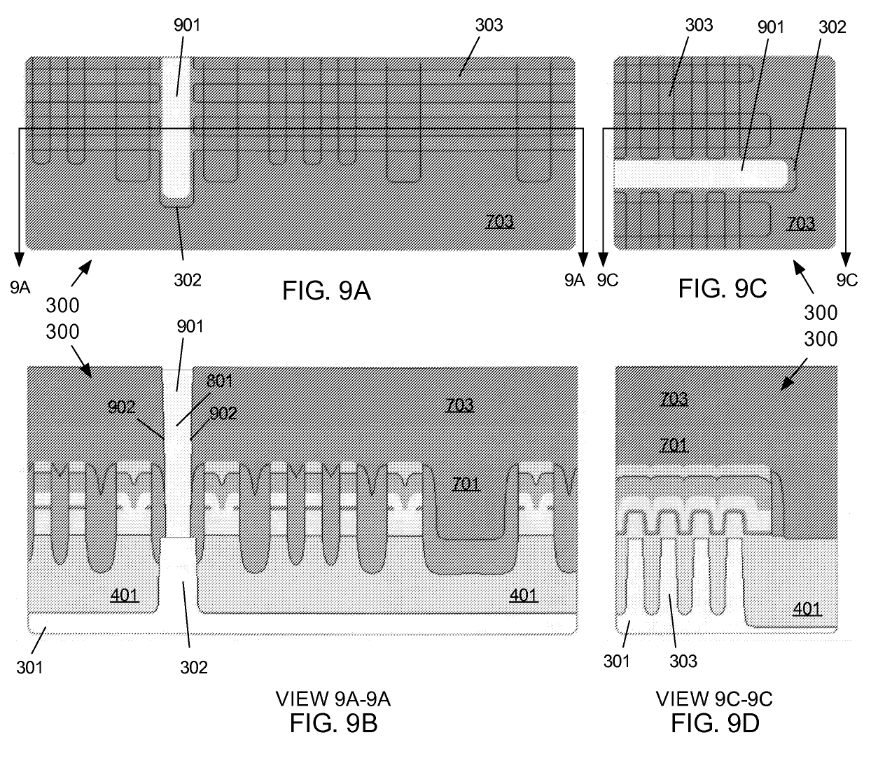

FIG. 9A depicts a top view of the exemplary embodiment of semiconductor device 300 after epitaxial (EPI) silicon 901 is selectively grown in common-source (CE) slot 801. FIG. 9B depicts a cross-sectional front elevation view of semiconductor device 300 as viewed along line 9A-9A in FIG. 9A. FIG. 9C depicts a rotated top view of a portion of semiconductor device 300 shown in FIG. 9A. FIG. 9D depicts a cross-sectional elevation side view of semiconductor device 300 as viewed along line 9C-9C in FIG. 9C. EPI silicon 901 is formed in a well-known manner so that it does not overgrow oxide 703. Because the wafer has been rotated 45 degrees so that the Si <100> plane has been exposed, silicon defects that are induced along the edges of the silicon-to-oxide interface 902 are minimized or eliminated. If EPI silicon 901 overgrows oxide 703, EPI silicon 901 can be etched back or removed using CMP in a subsequent step to obtain the benefits of eliminating defects in laterally grown EPI silicon.

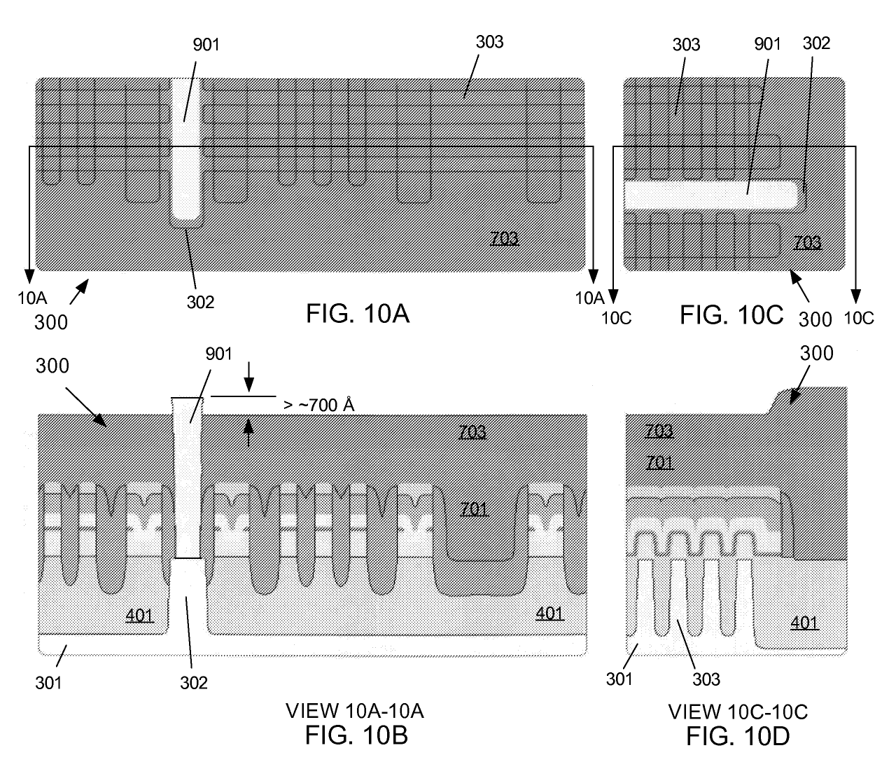

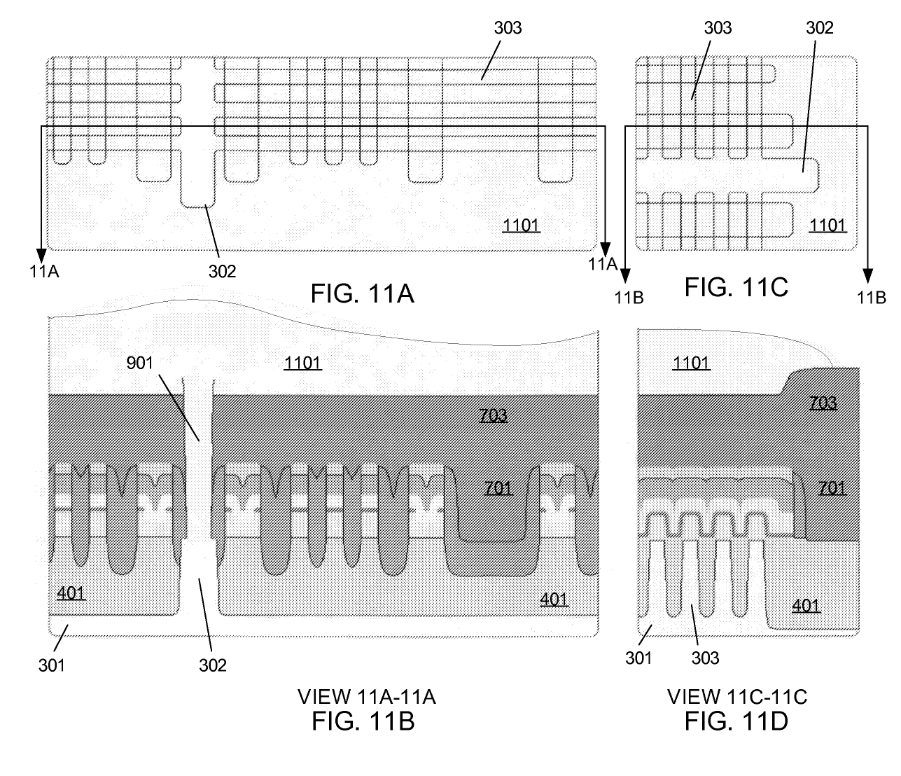

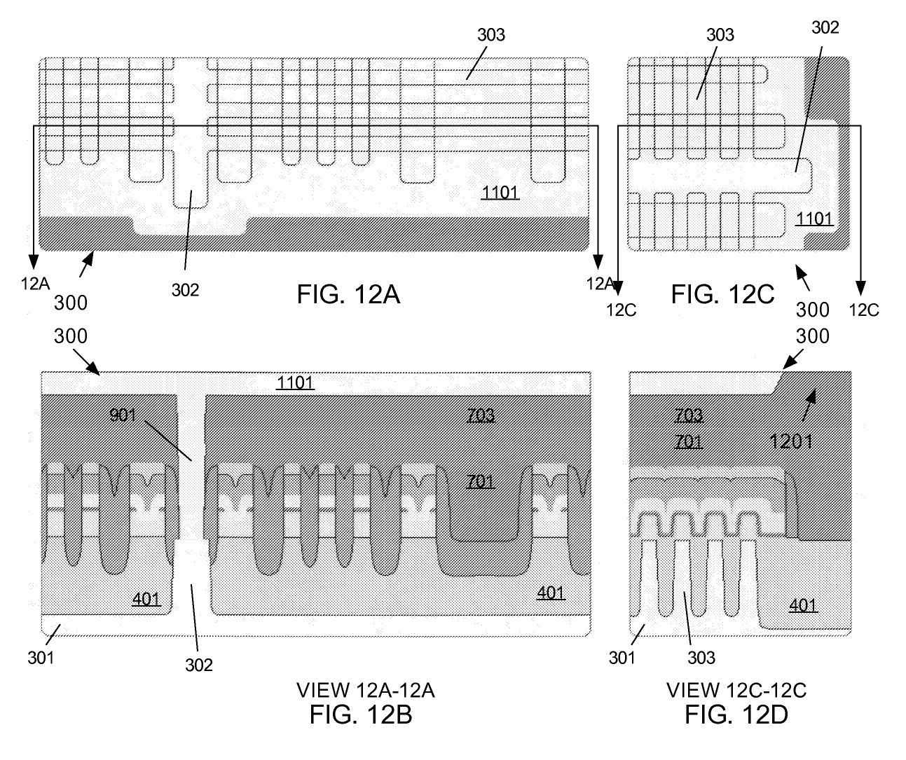

FIG. 10A depicts a top view of the exemplary embodiment of semiconductor device 300 after etching oxide 703 to about 700 Å or more below the top of EPI silicon 901. FIG. 10B depicts a cross-sectional front elevation view of semiconductor device 300 as viewed along line 10A-10A in FIG. 10A. FIG. 10C depicts a rotated top view of a portion of semiconductor device 300 shown in FIG. 10A. FIG. 10D depicts a cross-sectional elevation side view of semiconductor device 300 as viewed along line 10C-10C in FIG. 10C. Semiconductor device 300 is photomasked to expose the array only. That is, because it is desired to only define the SOI layer in the array, the phrase “expose the array only” means to provide a step-height difference between the array and the periphery of the array. The oxide hedge in the periphery assists the silicon uniformity because silicon CMP can stop on the peripheral oxide. Additionally, if “dummy” features are added in the periphery, then the “dummy” features can be opened up as well to help improve the uniformity during silicon CMP. The exposed area is wet etched in a well-known manner using HF to recess oxide 703 to be about 700 Å or more below the top of EPI silicon 901. Defects due to differences in the Coefficient of Thermal Expansion (CTE) in subsequently laterally overgrown EPI silicon are eliminated when oxide 703 is recess to about 700 Å or more below the top of EPI silicon 901. The thicker oxide at 1001 also serves as a CMP stop during subsequent silicon CMP (FIGS. 12A-12D).

FIG. 11A depicts a top view of the exemplary embodiment of semiconductor device 300 after selective lateral overgrowth of EPI silicon 1101 using EPI silicon 901 as a seed. FIG. 11B depicts a cross-sectional front elevation view of semiconductor device 300 as viewed along line 11A-11A in FIG. 11A. FIG. 11C depicts a rotated top view of a portion of semiconductor device 300 shown in FIG. 11A. FIG. 11D depicts a cross-sectional side elevation view of semiconductor device 300 as viewed along line 11C-11C in FIG. 11C.

FIG. 12A depicts a top view of the exemplary embodiment of semiconductor device 300 after CMP of laterally grown EPI silicon 1101 using oxide hedges 1201 (FIG. 12D) as a stop for the CMP. FIG. 12B depicts a cross-sectional front elevation view of semiconductor device 300 as viewed along line 12A-12A in FIG. 12A. FIG. 12C depicts a rotated top view of a portion of semiconductor device 300 shown in FIG. 12A. FIG. 12D depicts a cross-sectional side elevation view of semiconductor device 300 as viewed along line 12C-12C in FIG. 12C. In an alternative exemplary embodiment, EPI silicon 1101 is first treated with a resist/planar etch in a well-known manner, followed by CMP. In yet another exemplary alternative embodiment, EPI silicon 1101 is H₂ annealed to planarize the surface before silicon CMP. Afterward, EPI silicon 1101 is ready for the next memory array structures.

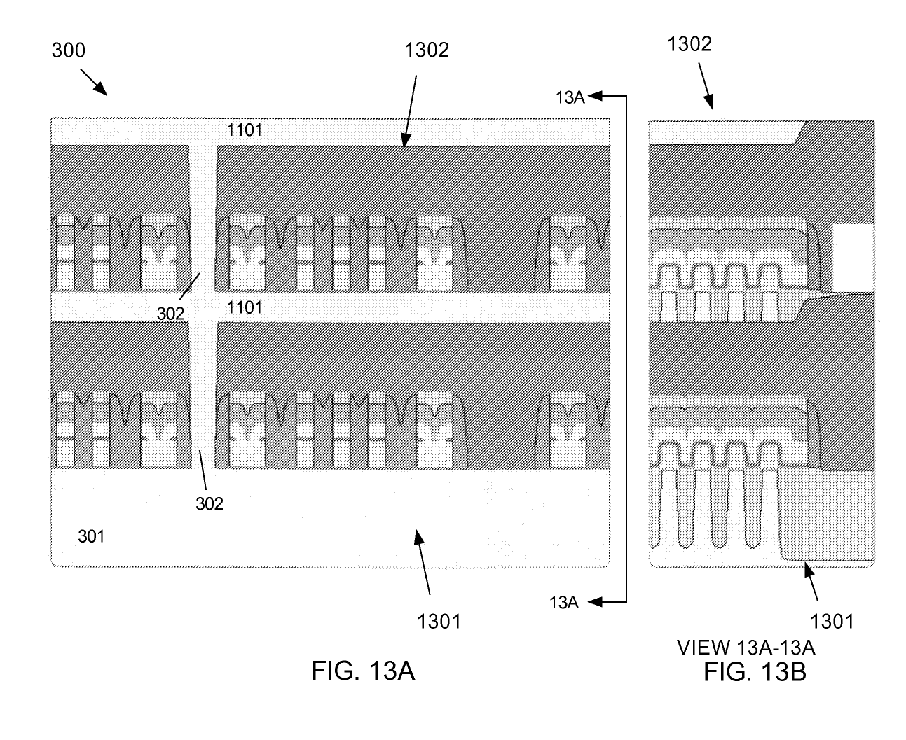

FIG. 13A depicts a cross-sectional front elevation view of exemplary embodiment of semiconductor 300 after two layers of NAND arrays 1301 and 1302 have been fabricated in a stacked manner according to the subject matter disclosed herein. FIG. 13B depicts a cross-sectional side elevation view of the exemplary embodiment of semiconductor 300 as viewed along line 13A-13A in FIG. 13A.

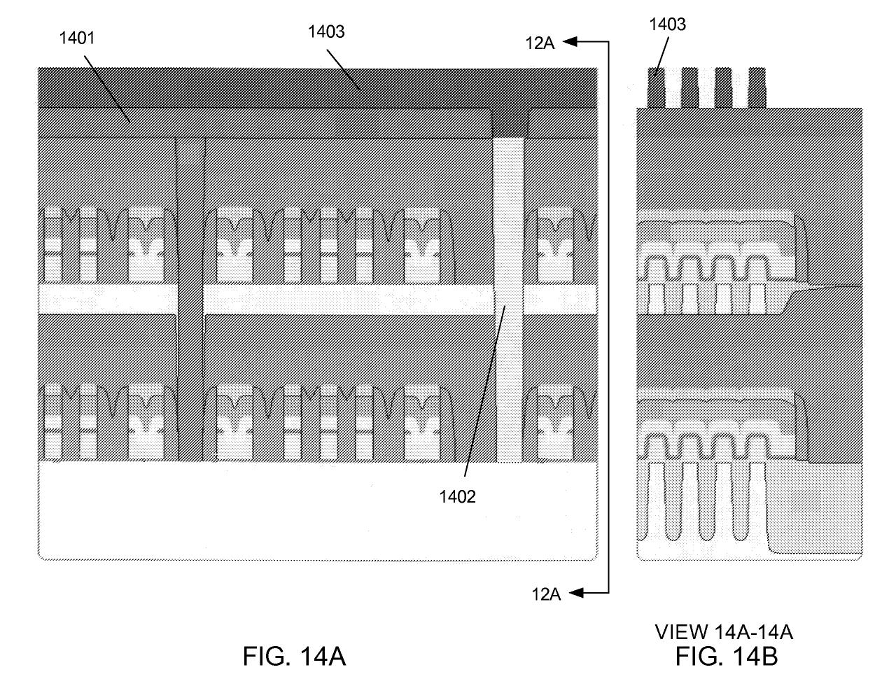

FIG. 14A depicts a cross-sectional front elevation view of exemplary embodiment of semiconductor 300 configured to be a multiple stack NAND memory array. FIG. 14B depicts a cross-sectional side elevation view of the exemplary embodiment of semiconductor 300 as viewed along line 14A-14A in FIG. 14A. In FIGS. 14A and 14B, a layer of silicon dioxide 1401 has been added in a well-known manner. A bit connection 1402 is formed in a well-known manner, and digit lines 1403 are added in a well-known manner. It should be understood that semiconductor 300 could include peripheral components and devices that are not shown in FIGS. 14A and 14B.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

What is claimed is:

1. A method, comprising:
forming at least a portion of a first integrated circuit on a crystalline silicon layer having a (100) crystal plane;
forming a dielectric layer on the first integrated circuit;
forming a trench through a top surface in the dielectric layer to expose the crystalline silicon layer, the trench having trench walls parallel to a <100> direction;
epitaxially growing silicon between trench walls formed in the dielectric layer so that a top surface of the epitaxially grown silicon is below the top surface of the dielectric layer;
etching the dielectric layer to below the top surface of the epitaxially grown silicon so that a top portion of the epitaxially grown silicon is exposed; and
laterally growing epitaxial silicon on the etched dielectric layer using the top portion of the epitaxially grown silicon as a seed to form a laterally grown epitaxial layer having a (100) crystal plane on the dielectric layer.

2. The method according to claim 1, wherein etching the dielectric layer to below the top surface of the epitaxially grown silicon etches the dielectric layer to below about 700 Å below the top surface of the epitaxially grown silicon.

3. The method according to claim 2, wherein etching the dielectric layer to below the top surface of the epitaxially grown silicon forms at least one shallow trench isolation area.

4. The method according to claim 3, wherein laterally epitaxially growing silicon on the etched dielectric layer laterally grows epitaxial silicon in the shallow trench isolation area.

5. The method according to claim 4, further comprising forming at least a portion of a second integrated circuit using the laterally grown epitaxial silicon having a (100) crystal plane.

6. The method according to claim 5, wherein the first and second integrated circuits form at least one of a NAND cell device, a NOR FLASH cell device, a personal computer random access memory device, a zero-capacitor random access memory device, a static random access memory device, an imager device, a one-time-programmable random access memory device, an electronically erasable programmable read only memory device, a logic circuitry device, a central processing unit device, a dynamic random access memory device, a magnetic random access memory device, a ferroelectric random access memory device, or a resistive random access memory device or combinations thereof.

7. A method, comprising:
providing a semiconductor wafer comprising a silicon surface with a (100) crystal plane and processing along a <110> direction relative to a crystalline structure of the silicon;
forming at least a portion of a first integrated circuit on the silicon layer with the (100) crystal plane;
forming a dielectric layer on the first integrated circuit;
forming a trench through a top surface in the dielectric layer to expose the crystalline silicon layer, the trench having trench walls parallel to a <100> direction;
epitaxially growing silicon between trench walls formed in the dielectric layer so that a top surface of the epitaxially grown silicon is below the top surface of the dielectric layer;
removing the dielectric layer to below the top surface of the epitaxially grown silicon so that a top portion of the epitaxially grown silicon is exposed; and
laterally growing epitaxial silicon on the etched dielectric layer using the top portion of the epitaxially grown silicon as a seed to form a laterally grown epitaxial layer having a (100) crystal plane on the dielectric layer.

8. The method according to claim 7, wherein etching the dielectric layer to below the top surface of the epitaxially grown silicon etches the dielectric layer to below about 700 Å below the top surface of the epitaxially grown silicon.

9. The method according to claim 8, wherein etching the dielectric layer to below the top surface of the epitaxially grown silicon forms at least one shallow trench isolation area.

10. The method according to claim 9, wherein laterally epitaxially growing silicon on the etched dielectric layer laterally grows epitaxial silicon in the shallow trench isolation area.

11. The method according to claim 10, further comprising forming at least a portion of a second integrated circuit using the laterally grown epitaxial silicon having a (100) crystal plane.

12. The method according to claim 11, wherein the first and second integrated circuits form at least one of a NAND cell device, a NOR flash cell device, a personal computer random access memory device, a zero-capacitor random access memory device, a static random access memory device, an imager device, a one-time-programmable random access memory device, an electronically erasable programmable read only memory device, a logic circuitry device, a central processing unit device, a dynamic random access memory device, a magnetic random access memory device, a ferroelectric random access memory device, or a resistive random access memory device, or combinations thereof.

13. A three-dimension stacked semiconductor device formed from a method, comprising:
forming at least a portion of a first integrated circuit on a crystalline silicon layer having a (100) crystal plane;
forming a dielectric layer on the first integrated circuit;
forming a trench through a top surface in the dielectric layer to expose the crystalline silicon layer, the trench having trench walls parallel to a <100> direction;
epitaxially growing silicon between trench walls formed in the dielectric layer so that a top surface of the epitaxially grown silicon is below the top surface of the dielectric layer;
etching the dielectric layer to below the top surface of the epitaxially grown silicon so that a top portion of the epitaxially grown silicon is exposed; and
laterally growing epitaxial silicon on the etched dielectric layer using the top portion of the epitaxially grown silicon as a seed to form a laterally grown epitaxial layer having a (100) crystal plane on the dielectric layer.

14. The device according to claim 13, wherein etching the dielectric layer to below the top surface of the epitaxially grown silicon etches the dielectric layer to below about 700 Å below the top surface of the epitaxially grown silicon.

15. The device according to claim 14, wherein etching the dielectric layer to below the top surface of the epitaxially grown silicon forms at least one shallow trench isolation area.

16. The device according to claim 15, wherein laterally epitaxially growing silicon on the etched dielectric layer laterally grows epitaxial silicon in the shallow trench isolation area.

17. The device according to claim 16, wherein the method forming the device further comprises forming at least a portion of a second integrated circuit using the laterally grown epitaxial silicon having a (100) crystal plane.

18. The device according to claim 17, wherein the first and second integrated circuits form at least one of a NAND cell device, a NOR FLASH cell device, a personal computer random access memory device, a zero-capacitor random access memory device, a static random access memory device, an imager device, a one-time-programmable random access memory device, an electronically erasable programmable read only memory device, a logic circuitry device, a central processing unit device, a dynamic random access memory device, a magnetic random access memory device, a ferroelectric random access memory device, or a resistive random access memory device, or combinations thereof.
